(19) United States
(12) Patent Application Publication
(10) Pub. No.: US 2016/0076169 A1
(43) Pub. Date: Mar. 17, 2016

(54) SUBSTRATES FOR GROWING GROUP III NITRIDE CRYSTALS AND THEIR FABRICATION METHOD

(71) Applicants: SIXPOINT MATERIALS, INC., Buellton, CA (US); SEOUL SEMICONDUCTOR CO., LTD., Seoul (KR)

(72) Inventor: Tadao HASHIMOTO, Santa Barbara, CA (US)

(21) Appl. No.: 14/849,553

(22) Filed: Sep. 9, 2015

Related U.S. Application Data
(60) Provisional application No. 62/049,036, filed on Sep. 11, 2014.

(51) Int. Cl. C30B 29/20

(52) U.S. Cl. CPC C30B 29/20

(57) ABSTRACT

In one instance, the invention provides a substrate for growing a thick layer of group III nitride. The substrate has a first surface prepared for epitaxial growth of group III nitride and a second surface, opposite to the first surface, having a plurality of grooves. The invention also provides a method of producing a thick layer or a bulk crystal of group III nitride using a grooved substrate. The grooved substrate in one configuration grows a thick layer or a bulk crystal of group III nitride with reduced bow and/or spontaneous separation from the substrate.

### CROSS REFERENCE TO RELATED APPLICATIONS

This application claims benefit of priority to U.S. patent application Ser. No. 62/049,036 entitled “Substrates for Growing Group III Nitride Crystals and Their Fabrication Method” by inventor Tadao Hashimoto and filed Sep. 11, 2014, the entire content of which is incorporated by reference in its entirety as if put forth in full herein.

This application is also related to the following U.S. patent applications:

PCT Utility Patent Application Serial No. US2005/024239, filed on Jul. 8, 2005, by Kenji Fujito, Tadao Hashimoto and Shuji Nakamura, entitled “METHOD FOR GROWING GROUP III-NITRIDE CRYSTALS IN SUPERCRITICAL AMMONIA USING AN AUTOCLAVE,” attorneys' docket number 30794.0129-WO-01 (2005-339-1);

U.S. Utility patent application Ser. No. 11/784,339, filed on Apr. 6, 2007, by Tadao Hashimoto, Makoto Saito, and Shuji Nakamura, entitled “METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-U1 (2006-204), which application claims the benefit under 35 U.S.C. Section 119(e) of U.S. Provisional Patent Application Ser. No. 60/790,310, filed on Apr. 7, 2006, by Tadao Hashimoto, Makoto Saito, and Shuji Nakamura, entitled “A METHOD FOR GROWING LARGE SURFACE AREA GALLIUM NITRIDE CRYSTALS IN SUPERCRITICAL AMMONIA AND LARGE SURFACE AREA GALLIUM NITRIDE CRYSTALS,” attorneys docket number 30794.179-US-P1 (2006-204);

U.S. Utility Patent Application Ser. No. 60/973,602, filed on Sep. 19, 2007, by Tadao Hashimoto and Shuji Nakamura, entitled “GALLIUM NITRIDE BULK CRYSTALS AND THEIR GROWTH METHOD,” attorneys docket number 30794.244-US-P1 (2007-809-1);

U.S. Utility patent application Ser. No. 11/977,661, filed on Oct. 25, 2007, by Tadao Hashimoto, entitled “METHOD FOR GROWING GROUP III-NITRIDE CRYSTALS IN A MIXTURE OF SUPERCRITICAL AMMONIA AND NITROGEN, AND GROUP III-NITRIDE CRYSTALS GROWN THEREBY,” attorneys docket number 30794.253-US-U1 (2007-774-2);

U.S. Utility Patent Application Ser. No. 61/067,117, filed on Feb. 25, 2008, by Tadao Hashimoto, Edward Letts, Masanori Ikari, entitled “METHOD FOR PRODUCING GROUP III-NITRIDE WAFERS AND GROUP III-NITRIDE WAFERS,” attorneys docket number 62158-30002.00 or SIXPOI-003;

U.S. Utility Patent Application Ser. No. 61/058,900, filed on Jun. 4, 2008, by Edward Letts, Tadao Hashimoto, Masanori Ikari, entitled “METHODS FOR PRODUCING IMPROVED CRYSTALLINITY GROUP III-NITRIDE CRYSTALS FROM INITIAL GROUP III-NITRIDE SEED BY AMMONOTHERMAL GROWTH,” attorneys docket number 62158-30004.00 or SIXPOI-002;

U.S. Utility Patent Application Ser. No. 61/058,910, filed on Jun. 4, 2008, by Tadao Hashimoto, Edward Letts, Masanori Ikari, entitled “HIGH-PRESSURE VESSEL FOR GROWING GROUP III NITRIDE CRYSTALS AND METHOD OF GROWING GROUP III NITRIDE CRYSTALS USING HIGH-PRESSURE VESSEL AND GROUP III NITRIDE CRYSTAL,” attorneys docket number 62158-30005.00 or SIXPOI-005;

U.S. Utility Patent Application Ser. No. 61/131,917, filed on Jun. 12, 2008, by Tadao Hashimoto, Masanori Ikari, Edward Letts, entitled “METHOD FOR TESTING III-NITRIDE WAFERS AND III-NITRIDE WAFERS WITH TEST DATA,” attorneys docket number 62158-30006.00 or SIXPOI-001;

U.S. Utility Patent Application Ser. No. 61/106,110, filed on Oct. 16, 2008, by Tadao Hashimoto, Masanori Ikari, Edward Letts, entitled “REACTOR DESIGN FOR GROWING GROUP III NITRIDE CRYSTALS AND METHOD OF GROWING GROUP III NITRIDE CRYSTALS,” attorneys docket number SIXPOI-004;

U.S. Utility Patent Application Ser. No. 61/694,119, filed on Aug. 28, 2012, by Tadao Hashimoto, Edward Letts, Sierra Hoff, entitled “GROUP III NITRIDE WAFER AND PRODUCTION METHOD,” attorneys docket number SIXPOI-015;

U.S. Utility Patent Application Ser. No. 61/705,540, filed on Sep. 25, 2012, by Tadao Hashimoto, Edward Letts, Sierra Hoff, entitled “METHOD OF GROWING GROUP III NITRIDE CRYSTALS,” attorneys docket number SIXPOI-014;

which applications are incorporated by reference herein in their entirety as if put forth in full below.

### BACKGROUND

1. Field of the Invention

The invention relates to a substrate used to produce a thick layer or a bulk crystal of group III nitride semiconductor materials such as GaN and AN. The invention also provides methods of producing a thick layer or a bulk crystal of group III nitride semiconductor materials. The thick layer or the bulk crystal of group III nitride are used to a produce wafer of group III nitride semiconductor, such as a GaN wafer.

2. Description of the Existing Technology

This document refers to several publications and patents as indicated with numbers within brackets, e.g., [x]. Following is a list of these publications and patents:
[1] R. Dwiliński, R. Doradziński, J. Garczyński, L. Sierzputowski, Y. Kanbara, U.S. Pat. No. 6,656,615.
[2] R. Dwiliński, R. Doradziński, J. Garczyński, L. Sierzputowski, Y. Kanbara, U.S. Pat. No. 7,132,730.
[3] R. Dwiliński, R. Doradziński, J. Garczyński, L. Sierzputowski, Y. Kanbara, U.S. Pat. No. 7,160,388.
[4] K. Fujito, T. Hashimoto, S. Nakamura, International Patent Application No. PCT/US2005/024239, WO07008198.
[5] T. Hashimoto, M. Saito, S. Nakamura, International Patent Application No. PCT/US2007/008743, WO07117689. See also US20070234946, U.S. application Ser. No. 11/784,339 filed Apr. 6, 2007.
[6] D'Evelyn, U.S. Pat. No. 7,078,731.
[7] Sakai et al., Applied Physics Letters vol. 71 (1997) p. 2259.

Each of the references listed in this document is incorporated by reference in its entirety as if put forth in full herein, and particularly with respect to their description of methods of making and using group III nitride substrates.

Gallium nitride (GaN) and its related group III nitride alloys are the key material for various optoelectronic and electronic devices such as LEDs, LDs, microwave power transistors, and solar-blind photo detectors. Currently LEDs are widely used in displays, indicators, general illuminations, and LDs are used in data storage disk drives. However, the majority of these devices are grown epitaxially on heterogeneous substrates, such as sapphire and silicon carbide because GaN substrates are extremely expensive compared to these heteroepitaxial substrates. The heteroepitaxial growth of group III nitride causes highly defected or even cracked films, which hinder the realization of high-end optical and electronic devices, such as high-brightness LEDs for general lighting or high-power microwave transistors.

To solve fundamental problems caused by heteroepitaxy, it is indispensable to utilize crystalline group III nitride. For the majority of devices, crystalline GaN wafers are favorable because it is relatively easy to control the conductivity of the wafer and GaN wafer will provide the smallest lattice/thermal mismatch with device layers. However, due to the high melting point and high nitrogen vapor pressure at elevated temperature, it has been difficult to grow GaN crystal ingots. Currently, the majority of commercially available GaN wafers are produced by a method called hydride vapor phase epitaxy (HVPE).

To obtain bulk crystals of GaN, from which GaN wafers can be sliced, various growth methods such as ammonothermal growth, flux growth, high-temperature solution growth have been developed. Ammonothermal method grows group III nitride crystals in supercritical ammonia [1-6]. The flux method and the high-temperature solution growth use a melt of group III metal. However, these methods typically require a GaN seed crystal. Since single crystalline GaN does not exist in nature, GaN wafers grown by HVPE are typically used as a seed crystal.

To produce group III-nitride wafers by HVPE, a thick layer (>500 microns) of group III-nitride is grown on a substrate, typically sapphire, silicon carbide, silicon or gallium arsenide. Then, the substrates are removed by mechanical grinding, laser-assisted separation or chemical etching. These methods, however, require additional process to remove the substrates.

There are several technologies on spontaneous separation (or auto-separation, self-separation, self-delamination) of the thick GaN film if a special buffer layer or patterning is made on the front side of crystalline substrates. For example, periodic SiO₂ stripe mask on the front side of the sapphire substrate enables selective growth of GaN [7]. Since the GaN layer is only partially adhered on the sapphire substrate, the thick GaN layer delaminates from the substrates upon cooling after growth. Similarly, creating periodic trenches on the front side of the substrate results in so-called cantilever epitaxy, and coalesced layer also tends to delaminate upon cooling. These selective growths typically change the propagation direction of dislocations, resulting in annihilation of the dislocations. However, this causes uneven distribution of dislocations on the surface of GaN, which is not favorable in lapping and polishing. In particular, chemical mechanical polishing (CMP) utilizes chemical effect, which is sensitive to dislocations. Uneven distribution of dislocations causes height fluctuation after CMP.

### SUMMARY OF THE INVENTION

In one instance, the invention provides a substrate for growing a thick layer or a bulk crystal of group III nitride having a thickness of more than 0.5 mm. The substrate such as sapphire, silicon carbide, quartz, glass, or gallium nitride has grooves on the backside, the side where group III nitride crystal may or may not be grown.

The invention also provides a method of growing a thick layer or a bulk crystal of group III nitride by using a substrate having grooves on the backside. Crystal growth methods suitable for growing thick films or bulk crystals of group III nitride primarily on one major face or side of the substrate, such as HVPE, are preferably used.

### BRIEF DESCRIPTION OF THE DRAWINGS

Referring now to the drawings in which like reference numbers represent corresponding parts throughout:

FIG. 1 is a schematic drawing of the substrate with a set of grooves on the backside, viewed from the substrate's edge.

In the figure each number represents the followings:

1. A substrate with grooves on the backside,

1a. A first side (front side) of the substrate

1b. A second side (back side) of the substrate

2. A groove,

3. Width of the groove,

4. Pitch of the groove

5. Depth of the groove

6. Thickness of the substrate.

FIG. 2 is a schematic drawing of the bottom view of a substrate, illustrating how multiple grooves are formed in the second side of the substrate.

In the figure each number represents the followings:

1b. A second side (backside) of the substrate,

2. A groove.

FIG. 3 is a microscope image of the back surface of a grooved sapphire substrate. In the figure each number represents the followings:

1b. A second side (backside) of the substrate,

2. A groove.

FIG. 4 is a microscope image of the groove surface made on the backside of a sapphire substrate. In the figure each number represents the followings:

1b. A second side (backside) of the substrate,

2. A groove.

2a. A scratch along the groove direction.

FIG. 5 is a schematic flow of the method of production. FIG. 5(A) is a substrate with a first side (front side) prepared for growth of group III nitride. FIG. 5(B) is a substrate with grooves made on the second side (back side). FIG. 5(C) is a substrate with group III nitride grown on the first side with thickness larger than that of the substrate. FIG. 5(D) is after spontaneous separation of the group III nitride film from the substrate.

In the figure each number represents the followings:

1. A substrate with grooves on the backside,

2. A groove.

2b. A crack.

7. A substrate

8. Group III nitride layer attached to the substrate

9. Group III nitride layer separated from the substrate.

FIG. 6 is a schematic drawing of bow of the group III nitride layer.

In the figure each number represents the followings:

10. A substrate or group III nitride layer with the substrate,

11. Bow amount.

### DETAILED DESCRIPTION OF THE INVENTION

Overview

The substrate of this invention in one instance enables thick growth of group III nitride such as GaN with reduced bow and optional spontaneous separation. Group III nitride is commonly used for optoelectronic devices and electronic devices although majority of devices utilizes heteroepitaxial substrates such as sapphire, silicon carbide, and silicon. This is due to lack of low-cost, high-quality free-standing group-III nitride wafers. Recently, GaN substrates have been produced with hydride vapor phase epitaxy (HVPE), ammonothermal method, and flux method, and AN wafers have been produced with HVPE and physical vapor transport methods. Among these methods, HVPE is most commonly used. HVPE production of GaN substrates involves growth of a thick GaN layer on a substrate and removal of the substrate.

When a thick layer of GaN or other group III nitride is grown on a heteroepitaxial substrate, the layer is highly stressed due to mismatches of lattice constant and thermal expansion coefficient. This stress causes bowing of the layer and the substrate. If the bowing exceeds the critical value, the layer and/or the substrate will crack. In addition, even homoepitaxial growth of bulk/thick GaN on GaN substrate sometimes causes bowing and cracking Thus, it is important to reduce bowing of the thick layer and/or substrate on which it is grown by reducing stress.

Another issue in the production process of a group III nitride such as GaN by HVPE is removal of the substrate. Several methods, such as mechanical grinding, laser lift-off and chemical etching, are currently used although these methods require an additional process to separate the substrate and new growth. Several cases of spontaneous separation of the GaN layer from the substrates have been reported. One method utilizes selective growth with a mask or trenches, nevertheless the selective growth results in gathering of dislocations in one region, leading to non-uniform distribution of dislocations. The termination points of these dislocations at the surface often cause pits during CMP process, therefore non-uniform distribution of the dislocations would cause macroscopic thickness variation over the wafer.

Technical Description of the Invention

This invention discloses a substrate for growth of a thick layer of group III nitride and which substrate may address one or more of the issues discussed above. The substrate has a major surface at a first or front side which is prepared for epitaxial growth of group III nitride, and the substrate has a second major surface or back side that is opposite to the first side and that has a plurality of grooves. The grooves reduce stress in the epitaxially-deposited group III nitride that is caused by epitaxial growth of group III nitride on a substrate, especially as compared to an otherwise identical substrate that has no grooves on the comparative substrate or as compared to an otherwise identical substrate that has grooves on the first or front side of a comparative substrate on which group III nitride is to be grown.

The first side of the substrate, which preferably has no grooves, can have a highly-polished surface and/or one or more buffer layers such as AlN or GaN applied to it to make the surface of the first side suitable for epitaxial deposition, whereas the second side may not be polished or as highly polished and/or may not have buffer layers applied to it. The second side may therefore not be suitable for epitaxial deposition, although in one variation of the invention the second side is also suitable for epitaxial deposition.

The substrate can be amorphous, polycrystalline, or single crystalline and can be a heteroepitaxial material such as quartz, glass, sapphire, silicon carbide or silicon, or the substrate may be a homoepitaxial material such as GaN or AlN. The substrate can have wurtzite crystal structure, for instance. In some instances, the substrate is single crystalline silicon, sapphire, GaN, or AlN. A substrate is typically at least 250 microns thick. A substrate may be at least 500 microns thick, or thickness may be between 250 and 500 microns, for instance.

Although there are some heteroepitaxial techniques utilizing trenches on a substrate, these methods typically create trenches or grooves on the front side of the substrate on which epitaxial growth will occur. On the other hand, the current invention utilizes grooves on the backside of the substrate where epitaxial growth will not necessarily occur.

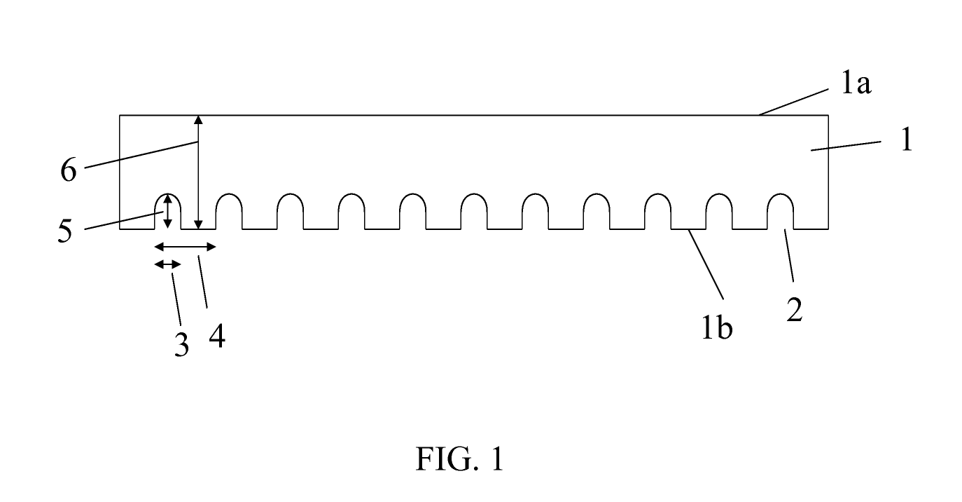

As shown in edge view in FIG. 1, the depicted substrate 1 has a first side or major surface 1a, and this surface is polished to a roughness Ra on the order of less than 1 nm for epitaxial growth of group III nitride. The second side or major surface 1b has a plurality of grooves 2.

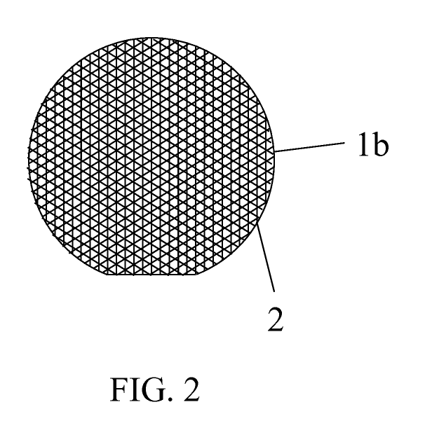

FIG. 2 provides a schematic view of the grooves across a major face or surface of the substrate. The backside of the substrate 1b has grooves 2 which, in this case, are along a crystallographic orientation of the substrate and/or of the group III nitride being formed, and preferably at least some of the grooves are located along a cleavage direction or plane in the substrate. This orientation of grooves with crystal cleavage direction or plane enables the substrate to flex more as group III nitride is deposited and as temperature changes than if identical grooves are placed in other directions along the substrate. For example, when c-plane sapphire is used as a substrate, the grooves are preferably made along m-planes of the sapphire. The grooves are preferably made symmetrically for all possible equivalent planes, i.e. (10-10) plane, (01-10) plane, and (1-100) plane. Depending on the situation, however, the grooves can be made along only one crystallographic plane or two crystallographic planes, although the stress in the grown group III nitride may become asymmetric in these cases.

The substrate consequently has a plurality of grooves on its second side, where the grooves have a spatial relationship with one another and/or with the substrate that allows the substrate to reduce bow in the substrate more than a comparative substrate bows as group III nitride is deposited and/or as temperature changes from epitaxial growth conditions to ambient temperature. A comparative substrate in this instance may have no grooves in it but be otherwise identical to the substrate of this invention. Alternatively, the comparative substrate may have grooves on a front-side on which group III nitride is deposited but not a back-side of the comparative substrate while being otherwise identical to the substrate of this invention. The grooved substrate of this invention preferably has sufficient rigidity that the surface of the first side has about the same bowing under epitaxial deposition conditions when group III nitride is first being deposited on the substrate as that surface has at room temperature.

The spatial relationship is determined by the size and placement of grooves on the substrate's second side. Parameters that can be used to characterize size and placement of grooves include groove width, groove depth, groove pitch, groove shape, groove orientation relative to crystallographic planes of the substrate (as explained above), scratches on the surface of the grooves, and substrate thickness, for instance. Combinations of each of these parameters can be used to provide the desired substrate flexibility.

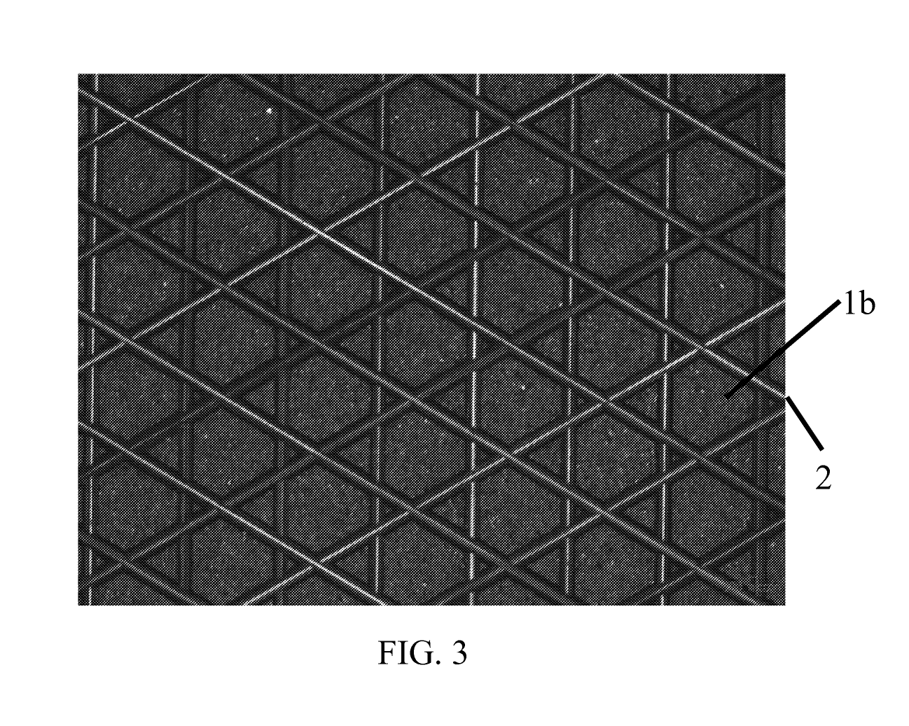

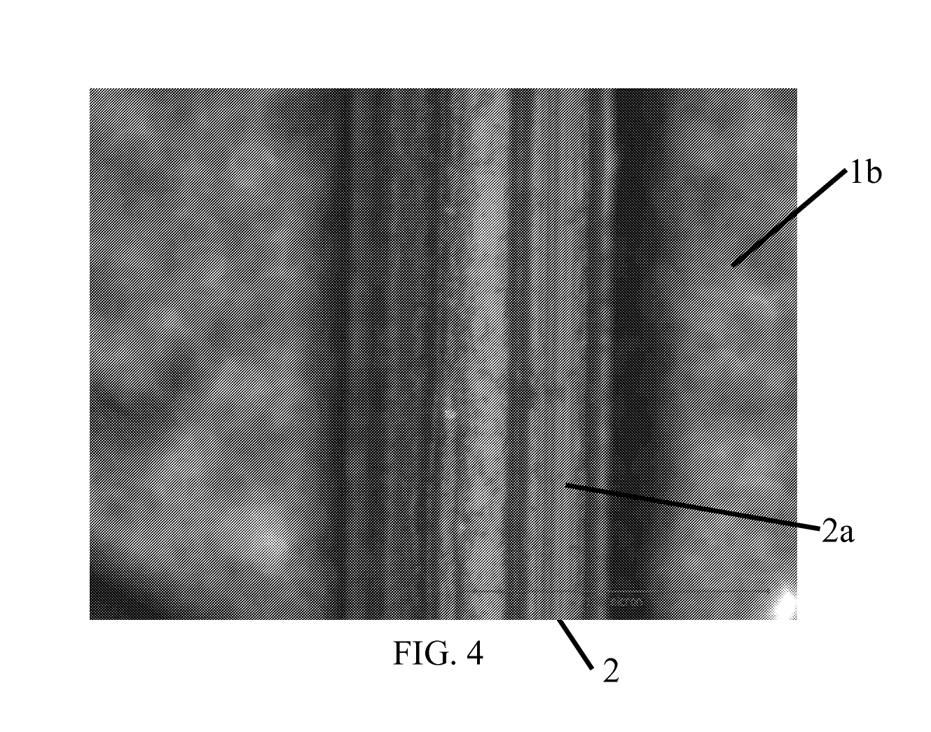

Referring to FIG. 1, in one instance, the width 3 of the grooves is preferably between 100 microns and 300 microns, and groove depth 5 is preferably between 50 microns and 75% of the thickness 6 of the substrate 1. Grooves are spaced from one another. The grooves may be parallel or intersecting. Parallel grooves may all be spaced the same distance from one another so that all parallel grooves have the same period. Alternatively, parallel grooves may be positioned on the substrate so that a first set of grooves has a first periodic spacing, and a second set of grooves has a second periodic spacing different from the first periodic spacing. Alternatively, the spacing between adjacent parallel grooves may not be periodic. Spacing between adjacent grooves may be smaller in the vicinity of the center of the second side of the substrate, where stress is greater, than the spacing between adjacent grooves in a peripheral region away from the center. The pitch 4 of individual or sets of grooves as discussed is preferably between 0.1 mm and 5 mm. These grooves may have the pattern illustrated in FIG. 2 and as explained above, for instance. The pattern for the set of grooves illustrated in FIG. 2 can have three-fold symmetry. The shapes formed by intersecting grooves may be identical, so that all grooves have one shape that is e.g. triangular, or the shapes may be a mixture of different shapes as depicted in FIG. 2, where some portions of the second side of the substrate are e.g. triangular and some are another shape such as hexagonal with different length or identical length sides. FIG. 3 is a microscope image of the actual grooved sapphire surface. The grooves may also have a curved bottom such as an arc-shaped bottom as shown in FIG. 1, or the bottom of the grooves may be flat or V-shaped depending on how the grooves are formed. It is preferable to have scratches along the grooves as shown in FIG. 4. One particular substrate having these grooves is a sapphire substrate, and a group III nitride such as gallium nitride is deposited on the first side of this substrate.

The groove width, depth, and pitch in this example are significantly greater than the width, depth, and pitch of grooves formed in a comparative substrate's first side on which group III nitride is grown. The need for planarity of the comparative substrate's first side during epitaxial deposition of group III nitride limits the size and placement of grooves in the comparative substrate's first side. The substrate as provided herein is therefore different from a substrate that only has grooves on the face on which group III nitride is to be grown, since the groove positions, shapes, and/or sizes differ so that the substrate affects group III nitride growth differently.

The substrate of this invention may have an un-damaged, planar first side of the substrate to ensure epitaxial growth of high-quality group III nitride. The grooves on the second (back) side reduce mechanical strength of the substrate. When the thickness of the group III nitride layer approaches or exceeds the thickness of the substrate, the stress caused by mismatch of crystal lattice and/or thermal expansion may be absorbed by these grooves by allowing portions of the substrate to move slightly by compressing and/or flexing or generating cracks initiated from the scratches formed in the grooves. This may reduce the stress in and/or bow of the group III nitride layer and also may induce spontaneous separation of the group III nitride layer from the substrate upon cooling.

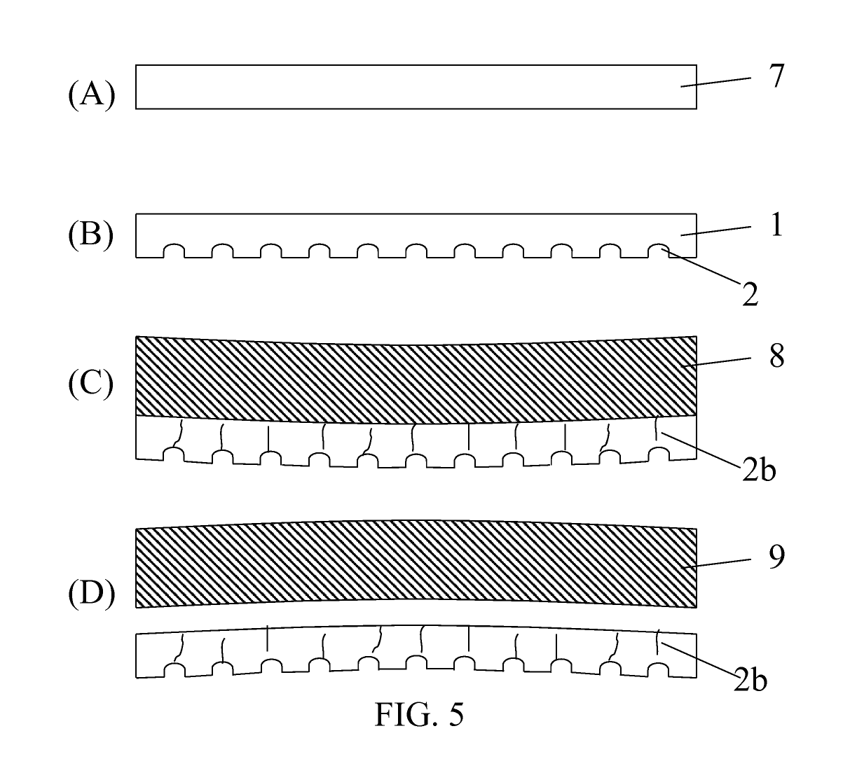

FIG. 5 presents a schematic process flow of this invention. A substrate 7 is prepared to have a suitable front surface for epitaxial growth of group III nitride (FIG. 5(A)). Plurality of grooves is made on the backside of the substrate to form substrate 1 (FIG. 5(B)). Compared to trenches or grooves in conventional technologies in which the grooves are formed in the substrate's first side, the groove width, depth, and pitch in the current example are significantly larger. In addition, it is preferable to have numerous mechanical scratches along the groove direction. Because of this nature, the grooves are most preferably created with a multiple wire saw that creates an arced groove bottom. Another method of forming grooves is chemical etching at room temperature or at elevated temperature. For example, a sapphire substrate can be etched by hot (>80° C.) phosphoric acid, and silicon carbide and silicon can be etched in the mixture of hydrofluoric acid and nitric acid, or molten alkali-hydroxide (sodium hydroxide, potassium hydroxide, etc.). Although it would require additional time, the grooves can be made using other mechanical way such as wafer dicers or by dry etching such as reactive ion etching. Grooves may also be laser-etched into a substrate surface.

The first side may be flat. Alternatively, the first side may have a periodic SiO₂ stripe mask on the first side as mentioned above for reference [7] and/or holes, cutouts, and/or grooves in the first side as described in e.g. reference [6].

The first (front) side of the substrate may be prepared for epitaxial deposition before and/or after grooves are formed or during the process of forming grooves. If the process to make grooves contaminates the surface of the first side upon which group III nitride will be deposited, the substrate is preferably cleaned and/or polished to remove the contamination. Group III nitride 8 such as GaN, AN, InN or one of their solid solutions is grown on the first side of the substrate as shown in FIG. 5(C). The growth method is preferably HVPE although other methods such as metalorganic chemical vapor deposition (MOCVD), molecular beam epitaxy (MBE), ammonothermal growth, flux growth, high-temperature solution growth, epitaxial sputtering, can be used.

When the thickness of the group III nitride layer becomes large, the substrate and the layer start to bow. If the layer experiences tensile stress such as for a sapphire substrate, the substrate 1 and the layer 8 become concave as shown in FIG. 5(C). Conversely, when the layer experiences compressive stress, the substrate 1 and the layer 9 become convex. In either case, the bow may be reduced by the grooves on the backside of the substrate. To produce a free-standing substrate of group III nitride, the layer thickness is preferably larger than 500 microns. Also, the layer thickness preferably exceeds the thickness of the substrate.

After growth of a thick layer of group III nitride, the group III nitride layer on the substrate is cooled. Upon cooling, the group III nitride layer may occasionally, fully or partially delaminate from the substrate as shown in FIG. 5(D). Although detailed mechanism of this spontaneous separation is unknown, the spontaneous separation tends to occur when the group III nitride layer thickness is more than 500 microns or the layer thickness exceeds the substrate thickness.

### Comparative Example—Example 1

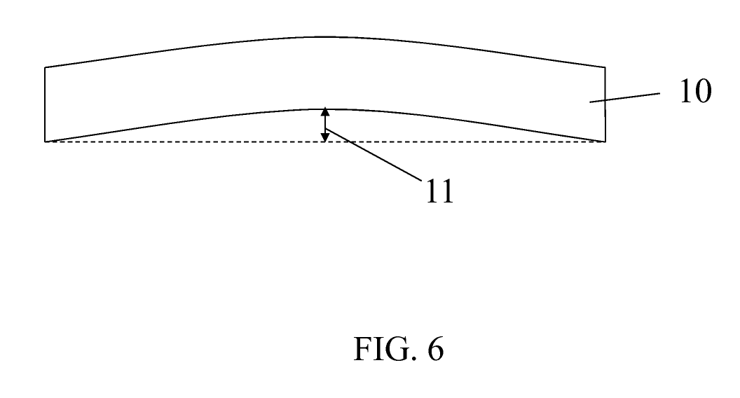

Thick layer of GaN was grown by HVPE on a sapphire substrate without any grooves. A single-side polished, c-plane sapphire substrate having miscut within 5 degree, having diameter of 2″ was loaded into a HVPE reactor. The group III source was GaCl synthesized in the reactor chamber by flowing HCl over molten Ga. The group V source was NH₃. First, a buffer layer of GaN was grown at about 900° C. with HCl flow rate of 20 sccm and NH₃ flow rate of 3.5 slm for 10 minutes. Then, the GaN thick layer was grown at about 1030° C. with HCl flow rate of 60 sccm and NH₃ flow rate of 2 slm for 16 hours. The total layer thickness of GaN was approximately 2900 microns. After growth, the GaN layer on the substrate was cooled, but the GaN layer did not separate from the substrate. The crystal bow was 607 microns toward the growth direction (convex). The bow 11 was measured as a height difference between the edge and the center of the substrate 10 (FIG. 6).

### Production of Grooved Substrate—Example 2

Grooves are made on the backside of a 2″ c-plane sapphire substrate. The miscut of the major face or surface was within 5 degree from c-plane sapphire. First, the sapphire substrate was mounted face down on a metal block with wax. Then, the assembly was loaded to a multiple wire saw. The wire diameter was approximately 160 microns, and wire pitch was 670 microns. Diamond slurry was supplied while the wire runs back and forth on the backside of the sapphire substrate. First the wire was set along (10-10) plane and approximately 160 micron-deep grooves were made over the entire back surface. Then, the wire was set along (1-100) plane and approximately 160 micron-deep grooves were made over the entire back surface. Lastly, the wire was set along (01-10) plane and approximately 160 micron-deep grooves were made over the entire back surface. Through these steps, a sapphire substrate with grooves having straight walls and arc-shaped bottoms in profile was produced on the backside of the substrate (schematic in FIG. 2). The groove depth was approximately 160 microns, the thickness of the substrate was approximately 430 microns, the groove width was approximately 160 microns and the groove pitch was approximately 670 microns. The directions of the grooves are within reasonable angular errors (+/−5 degree) from m-planes. By using a multiple wire saw, wide and deep grooves can be made in less than an hour.

After the wire saw process, the substrate and the metal plate were heated to melt the wax. The substrate was removed from the metal plate and rinsed with acetone and isopropanol. This cleaning step removes residual wax and diamond slurry from the substrate.

### Growth of Thick Group III Nitride on a Grooved Substrate—Example 3

Similar to the method in Example 1, a thick GaN layer was grown on a grooved sapphire substrate produced in Example 2. The GaN layer was grown on a smooth ungrooved top surface of the substrate, with no GaN grown on the grooved surface exposed on the bottom of the substrate. HVPE growth condition was same as Example 1. After growth, the total thickness of the GaN was approximately 3600 microns.

The GaN layer spontaneously separated from the sapphire substrate upon cooling. The bow of the GaN layer was 138 microns towards the growth direction (convex), which is greatly reduced from the value in Example 1 (607 micron convex). The bow was measured as the height difference between the edge and the center of the GaN layer.

Upon self-separation of the GaN layer, the sapphire substrate was broken into several pieces along the grooves, which indicates that the grooves induced cracking in the sapphire substrate. Since the groove direction is along the cleavage direction of sapphire (i.e. m-plane), the grooves helped cleavage or cracking of sapphire. Scratches in the grooves in this particular instance may also have aided cleavage or cracking, although scratches are not essential. Substrate cracking and/or breakage may be the mechanism of spontaneous separation and reduced bow.

The cracking along the grooves may be promoted by abrasive nature of the multiple wire saw. In addition, a multiple wire saw enables to make grooves with uniform depth, width and pitch. This may also affect the effective reduction of stress at the interface of the substrate and new growth as well as in the grown ingot due to a highly symmetrical configuration of grooves, especially grooves positioned along cleavage planes in the substrate.

The groove width in this example was 160 microns, which was determined by the diameter of the wire. If wire with a different diameter is used, the groove width can be changed. However, to maintain certain wire strength, the wire diameter is typically larger than 100 microns. In addition, if the groove width is too small, the effect of reducing stress may be limited. On the contrary, if the width is too large, the substrate becomes too fragile. In one instance, the groove width is between 100 microns and 300 microns.

The groove depth of this example was 160 microns. The groove depth can be easily changed by adjusting the wire height relative to the substrate. If the depth is too small, the effect of reducing stress would be limited. On the contrary, if the depth is too large, the substrate becomes too fragile. The grooves in one instance may be between 50 microns to 75% of the thickness of the substrate.

The groove pitch of this example was 670 microns, which was determined by the wire pitch of the wire saw. It can be easily changed by using a wire roller with an appropriate groove pitch. If the groove pitch is too large the effect of reducing stress would be limited. On the contrary, if the groove pitch is too small, the substrate becomes too fragile. The groove pitch in one instance is between 0.1 mm to 5 mm.

The growth conditions including growth time was same for Example 1 and Example 3, nevertheless the GaN layer thickness was surprisingly increased by approximately 24% in Example 3. Reduced stress by the substrate grooves during growth may therefore promote crystal growth of GaN, resulting in a greater growth rate of GaN using a substrate of this invention over a comparative substrate that does not have grooves on the second side of the substrate but is otherwise identical.

Since the front side of the substrate has the same properties as a standard sapphire substrate, no special growth step is needed to obtain high-quality GaN film as is required when grooves are cut into the front side of the substrate. In addition, since selective growth required for grooves on a first side is not used, there is no dislocation gathering, which will cause a problem in CMP process.

The obtained 3.6 mm-thick free-standing GaN was processed to fabricate a GaN substrate by grinding, lapping and CMP. The final thickness of the GaN substrate was 529 microns.

Advantages and Improvements

The substrate with grooves on the backside in this invention can provide a group III nitride layer with reduced bow and optional spontaneous separation. A simple process using a multiple wire saw produces a substrate with backside grooves. The grooves on the backside of the substrate can reduce bow of the group III nitride layer through reduction of stress. The grooves may also induce spontaneous separation of the group III nitride layer from the substrate. The optionally smooth front surface of the substrate enables high-quality growth of group III nitride on the front side, without requiring special processing steps as are needed when the front side of the substrate is grooved. This feature may help in realizing smooth surface of GaN after CMP finishing.

Accordingly, following are various examples of what is provided by the invention:
1. A substrate for growing a group III nitride layer, and wherein the substrate has

(a) a first side suitable for epitaxial growth of bulk group III nitride, and

(b) a second side opposite to the first side of the substrate and having a plurality of grooves.
2. A substrate according to paragraph 1 wherein width of said grooves is individually between 100 microns and 300 microns and depth of said grooves is individually between 50 microns and 75% of a thickness of the substrate.
3. A substrate according to paragraph 1 or paragraph 2 wherein pitch of the grooves is individually between 0.1 mm and 5 mm.
4. A substrate according to any of paragraphs 1 through 3 wherein the grooves are along crystallographic orientations of the substrate.
5. A substrate according to paragraph 4 wherein the crystallographic orientation is a cleavage direction of the substrate.
6. A substrate according to any of paragraphs 1 through 5 wherein the plurality of grooves have a size, shape, and placement on said second side such that the substrate provides less bowing in a group III nitride layer formed on said substrate than a comparative substrate that is otherwise identical but does not have said grooves on the second side of the comparative substrate.
7. A substrate according to any of paragraphs 1 through 5 wherein the grooves have a size, shape, and placement on said second side such that the substrate provides a greater rate of growth of a group III nitride layer on said substrate than a comparative substrate that is otherwise identical but does not have said grooves on the second side of the comparative substrate.
8. A substrate according to any of paragraphs 1 through 5 wherein the grooves have a size, shape, and placement on said second side such that the substrate fully or partially separates from a group III nitride layer grown on the first side of the substrate when the group III nitride layer has a thickness of more than 500 microns.
9. A substrate according to any of paragraphs 1 through 8 wherein the grooves are spaced more closely in a central area of the second side than toward an edge of the second side.
10. A substrate according to any of paragraphs 1 through 9 wherein the substrate is amorphous.
11. A substrate according to any of paragraphs 1 through 9 wherein the substrate is a single crystal.
12. A substrate according to paragraph 11 wherein the substrate has wurtzite crystal structure.
13. A substrate according to paragraph 12wherein the substrate is single crystalline sapphire or single crystalline GaN.
14. A substrate according to paragraph 13 wherein the first side and the second side are c-planes of said single crystalline sapphire having miscut within 5 degree.
15. A substrate according to paragraph 14 wherein the grooves have three-fold symmetry along m-planes of the single crystalline sapphire or single crystalline GaN.
16. A substrate according to any of paragraphs 1 through 15 wherein the grooves are formed using a multiple wire saw.
17. A substrate according to paragraph 16 wherein the surface of the grooves have mechanical scratches along the groove direction.
18. A substrate according to any of paragraphs 1 through 17 wherein the group III nitride is GaN.
19. A substrate according to any of paragraphs 1 through 18 wherein the first side has no grooves.
20. A substrate according to any of paragraphs 1 through 19 wherein the substrate has a buffer layer on the first side of the substrate.
21. A method of producing a group III nitride ingot comprising growing an amount of a group III nitride layer on a first side of a substrate that has a second grooved side opposite to the first side, wherein said amount is sufficient to provide a thickness to the group III nitride layer that is greater than a thickness of the substrate.
22. A method according to paragraph 21 and further comprising spontaneously separating the substrate from the group III nitride layer.
23. A method according to paragraph 21 or paragraph 22 wherein groove width is between 100 microns and 300 microns and groove depth is between 50 microns and 75% of the thickness of the substrate.
24. A method according to any of paragraphs 21 through 23 wherein pitch of the grooves is between 0.1 mm and 5 mm.
25. A method according to any of paragraphs 21 through 24 wherein the grooves are positioned along crystallographic orientations of the substrate.
26. A method according to any of paragraphs 21 through 25 wherein the surface of the grooves have mechanical scratches along the groove.
27. A method according to paragraphs 21 through 26 wherein the grooves are formed using a multiple wire saw.
28. A method according to any of paragraphs 21 through 27 wherein the substrate is c-plane single crystalline sapphire or GaN.
29. A method according to paragraph 28 wherein the grooves are made with a threefold symmetry along m-planes of the single crystalline sapphire or GaN.
30. A method according to any of paragraphs 21 through 29 wherein the group III nitride is GaN.
31. A method according to any of paragraphs 21 through 30 wherein the group III nitride is grown by hydride vapor phase epitaxy.
32. A method of producing a group III nitride ingot comprising growing an amount of a group III nitride layer on the first side of the substrate of any of paragraphs 1 through 20.
33. An ingot formed by a method of any of paragraphs 21 through 32.

Possible Modifications

Although the preferred embodiment describes bulk crystals of GaN, similar benefit of this invention can be expected for other group III nitride solid solutions of various composition, such as AN, AlGaN, InN, InGaN, or GaAlInN.

Although the preferred embodiment describes a sapphire substrate, other material such as silicon carbide, silicon, quartz, gallium arsenide, gallium phosphide, gallium nitride, aluminum nitride, lithium gallate, lithium aluminate, magnesium gallate, magnesium aluminate can be used. The substrate may be a hetero-substrate or a homo-substrate.

Although the preferred embodiment describes HVPE as a growth method for growth on one side of a substrate, other growth method such as MOCVD, MBE, ammonothermal method, flux method, high-pressure solution growth, physical vapor transport can be used to grow on one side (with, e.g. masking on the back side where the method would typically grow on both sides) or to grow on both sides of the substrate.

Although the preferred embodiment describes a multiple wire saw to make grooves, other mechanical, chemical, physical methods such as dicing, wet etching, dry etching can be used.

What is claimed is:

1. A substrate for growing a group III nitride layer, and wherein the substrate has
(a) a first side suitable for epitaxial growth of bulk group III nitride, and
(b) a second side opposite to the first side of the substrate and having a plurality of grooves.

2. A substrate according to claim 1 wherein width of said grooves is individually between 100 microns and 300 microns and depth of said grooves is individually between 50 microns and 75% of a thickness of the substrate.

3. A substrate according to claim 1 wherein pitch of the grooves is individually between 0.1 mm and 5 mm.

4. A substrate according to claim 1 wherein the grooves are along crystallographic orientations of the substrate.

5. A substrate according to claim 4 wherein the crystallographic orientation is a cleavage direction of the substrate.

6. A substrate according to claim 1 wherein the plurality of grooves have a size, shape, and placement on said second side such that the substrate provides less bowing in a group III nitride layer formed on said substrate than a comparative substrate that is otherwise identical but does not have said grooves on the second side of the comparative substrate.

7. A substrate according to claim 1 wherein the grooves have a size, shape, and placement on said second side such that the substrate provides a greater rate of growth of a group III nitride layer on said substrate than a comparative substrate that is otherwise identical but does not have said grooves on the second side of the comparative substrate.

8. A substrate according to claim 1 wherein the grooves have a size, shape, and placement on said second side such that the substrate fully or partially separates from a group III nitride layer grown on the first side of the substrate when the group III nitride layer has a thickness of more than 500 microns.

9. A substrate according to claim 1 wherein the grooves are spaced more closely in a central area of the second side than toward an edge of the second side.

10. A substrate according to claim 1 wherein the substrate is single crystalline sapphire.

11. A substrate according to claim 10 wherein the first side and the second side are c-planes of said single crystalline sapphire having miscut within 5 degree.

12. A substrate according to claim 11 wherein the grooves have three-fold symmetry along m-planes of the single crystalline sapphire.

13. A substrate according to claim 1 wherein the grooves are formed using a multiple wire saw.

14. A substrate according to claim 13 wherein the surface of the grooves have mechanical scratches along the groove direction.

15. A substrate according to claim 1 wherein the first side has no grooves.

16. A substrate according to claim 1 wherein the substrate has a buffer layer on the first side of the substrate.

17. A substrate according to claim 1 wherein the group III nitride is GaN.

18. A substrate according to claim 17 wherein the grooves are along crystallographic orientations of the substrate.

19. A substrate according to claim 18 wherein the crystallographic orientation is a cleavage direction of the substrate.

20. A substrate according to claim 19 wherein the first side and the second side are c-planes of said single crystalline sapphire having miscut within 5 degree and wherein the grooves have three-fold symmetry along m-planes of the substrate.
